(19) United States
(12) Patent Application Publication
(10) Pub. No.: US 2013/0308262 A1
(43) Pub. Date: Nov. 21, 2013

(54) HINGE MODULE AND PORTABLE ELECTRONIC DEVICE

(71) Applicants: Chieh-Cheng Chang, TAIPEI CITY (TW); Huang-Yuan Huang, TAIPEI CITY (TW)

(72) Inventors: Chieh-Cheng Chang, TAIPEI CITY (TW); Huang-Yuan Huang, TAIPEI CITY (TW)

(73) Assignee: PEGATRON CORPORATION, Taipei City (TW)

(21) Appl. No.: 13/749,440

(22) Filed: Jan. 24, 2013

(30) Foreign Application Priority Data
May 21, 2012 (TW) 101117997

(51) Int. Cl. H05K 5/02

(52) U.S. Cl. CPC H05K 5/0226
USPC 361/679.09; 361/679.01; 16/365

(57) ABSTRACT

A hinge module applying for a first body pivotally disposed at a second body includes an axle having a baffle, a first stand, a second stand, an auxiliary stand, a washer and a pressing-element. The first stand includes a first connecting part fixed to the axle and a first fixing part fixed to the first body. The second stand includes a second connecting part pivotally connected to the axle and a second fixing part fixed to the second body. The auxiliary stand includes a third connecting part pivotally connected to the axle and a third fixing part fixed to the first or the second body. The washer is disposed between the axle and the third connecting part. The axial width of the washer is greater than that of the third connecting part. The pressing-element presses the second connecting part and the washer along an axial direction of the axle.

### CROSS-REFERENCE TO RELATED APPLICATION

This application claims the priority benefit of Taiwan application serial no. 101117997, filed on May 21, 2012. The entirety of the above-mentioned patent application is hereby incorporated by reference herein and made a part of this specification.

### BACKGROUND OF THE INVENTION

1. Field of the Invention

The present invention relates to a hinge module, and in particular, to a hinge module applicable to a portable electronic device.

2. Description of Related Art

In the current information age, people are becoming more and more dependent on electronic devices. For the demands of high efficiency and convenience, electronic devices such as laptop computer, etc., have become indispensable to the modern people's life and work.

In general, this type of the electronic device mainly includes two bodies. Each of the two bodies is composed of two casing. Taking the laptop computer for example, the top body has an outer casing, so called component A, and an inner casing, so called component B, located at the same side with the display module. The bottom body has an inner casing, so called component C, located at the same side with the keyboard module, and an outer casing, so called component D, contacting the desk. The outer casing (component A) of the top body and the outer casing (component D) of the bottom body of the laptop computer are usually connected to each other by a hinge module, such that the top body is capable of rotating relative to the bottom body.

Due to miniaturizing of the size of the electronic device, the volume of the two bodies becomes smaller, and the inner space thereof decreases accordingly. The size of the fixing structure in the hinge module for being fixed to the casing also shrinks due to the limited space, such that the stability of the pivot connection between the two bodies is affected. When a user rotates the body of the electronic device, the hinge module thereof may wobble. Currently, part of the electronic devices uses screw connection along with glue adhering according to the inner spaces thereof to fix the hinge module to the casing. However, when the assembling is improper or the hinge module and the casing needed to be disassembled for maintenance, the method of gluing makes the hinge module and the casing connected thereto can not be reworked. Furthermore, when the body of the electronic device bears greater rotation force, the glue between the hinge module and the casing may also encounters the situations of cracking due to inefficient strength.

### SUMMARY OF THE INVENTION

The present invention provides a hinge module which provides the two bodies connected thereto with satisfactory quality of pivot connection.

The present invention provides a portable electronic device adopting the hinge module described above such that the two bodies thereof have satisfactory quality of pivot connection.

A hinge module applying for a first body pivotally disposed at a second body is provided. The hinge module includes an axle, a first stand, a second stand, an auxiliary stand, a washer and a pressing element. The axle has a baffle. The first stand includes a first connecting part and a first fixing part. The first connecting part is fixed to the axle, and the first fixing part is fixed to the first body. The second stand includes a second connecting part and a second fixing part. The second connecting part is pivotally connected to the axle, and the second fixing part is fixed to the second body. The auxiliary stand includes a third connecting part and a third fixing part. The third connecting part is pivotally connected to the axle, and the third fixing part is suitable for being fixed to the first body or the second body. The washer is disposed on the axle and located between the axle and the third connecting part. The width of the washer along an axial direction of the axle is greater than the width of the third connecting part along the axial direction of the axle. The pressing element is fixed to the axle. The second connecting part, the third connecting part and the washer is located between the baffle and the pressing element. The pressing element provides pressure to the baffle along the axial direction of the axle.

In one embodiment of the present invention, the hinge module further includes a pair of first gaskets disposed on the axle, and the washer is located between the pair of first gaskets.

In one embodiment of the present invention, the hinge module further includes a pair of second gaskets disposed on the axle, and the second connecting part is located between the pair of second gaskets.

In one embodiment of the present invention, the hinge module further includes an elastic element disposed on the axle and located between the first gasket and the second gasket adjacent to each other.

In one embodiment of the present invention, the distance between the third fixing part and the axle is smaller than the distance between the first fixing part or the second fixing part and the axle.

In one embodiment of the present invention, the outer diameter of the washer and the inner diameter of the third connecting part are smaller than the outer diameter of the pressing element.

A portable electronic device including a first body, a second body and at least one hinge module is further provided. Each hinge module includes an axle, a first stand, a second stand, an auxiliary stand, a washer and a pressing element. The axle has a baffle. The first stand includes a first connecting part and a first fixing part. The first connecting part is fixed to the axle, and the first fixing part is fixed to the first body. The second stand includes a second connecting part and a second fixing part. The second connecting part is pivotally connected to the axle, and the second fixing part is fixed to the second body. The auxiliary stand includes a third connecting part and a third fixing part. The third connecting part is pivotally connected to the axle, and the third fixing part is suitable for being fixed to the first body or the second body. The washer is disposed on the axle and located between the axle and the third connecting part. The width of the washer along an axial direction of the axle is greater than the width of the third connecting part along the axial direction of the axle. The pressing element is fixed to the axle. The second connecting part, the third connecting part and the washer is located between the baffle and the pressing element. The pressing element provides pressure to the baffle along the axial direction of the axle.

In one embodiment of the present invention, the portable electronic device further includes a keyboard module and a display module. Each of the first body and the second body has an outer housing and an inner casing. The keyboard module is located at the inner casing of the first body, and the display module is located at the inner casing of the second body.

In one embodiment of the present invention, the first fixing part is fixed to the outer housing of the first body. The second fixing part and the third fixing part are fixed to the outer housing of the second body.

In one embodiment of the present invention, the hinge module further includes a pair of first gaskets disposed on the axle, and the washer is located between the pair of first gaskets.

In one embodiment of the present invention, the hinge module further includes a pair of second gaskets disposed on the axle, and the second connecting part is located between the pair of second gaskets.

In one embodiment of the present invention, the hinge module further includes an elastic element disposed on the axle and located between the first gasket and the second gasket adjacent to each other.

In one embodiment of the present invention, the distance between the third fixing part and the axle is smaller than the distance between the first fixing part or the second fixing part and the axle.

In one embodiment of the present invention, the outer diameter of the washer and the inner diameter of the third connecting part are smaller than the outer diameter of the pressing element.

Based on the above, the hinge module of the present invention uses the auxiliary stand thereof to help being fixed to the first body or the second body, so as to enhance the connection strength between the hinge module and the first body or the second body. Moreover, in the present invention, the rework between the hinge module and the first body or the second body is simple, such that the convenience in manufacture and maintenance is significantly improved. Furthermore, by means of the axial width of the washer greater than the axial width of the third connecting part of the auxiliary stand, the pressure of the pressing element is transmitted to the second connecting part by the washer, so as to diminish the negative impact on the auxiliary stand. Therefore, when the first body rotates relative to the second body, the auxiliary stand may rotate freely without being affected by the torsion of the hinge module, so as to elongate the lifetime of the connection between the auxiliary stand and the first body or the second body.

In order to make the aforementioned and other features and advantages of the invention more comprehensible, embodiments accompanying figures are described in detail below.

### BRIEF DESCRIPTION OF THE DRAWINGS

FIG. 1A is a schematic view of a hinge module according to one embodiment of the present invention.

FIG. 1B is a partial enlarged view of the hinge module in FIG. 1A.

FIG. 1C is a schematic cross-sectional view of the hinge module in FIG. 1A along line A-A.

FIG. 2A is a schematic view of a portable electronic device according to an embodiment of the present invention.

FIG. 2B is a schematic view of the portable electronic device which the inner casings of the first body and the second body in FIG. 2A is omitted.

### DESCRIPTION OF EMBODIMENTS

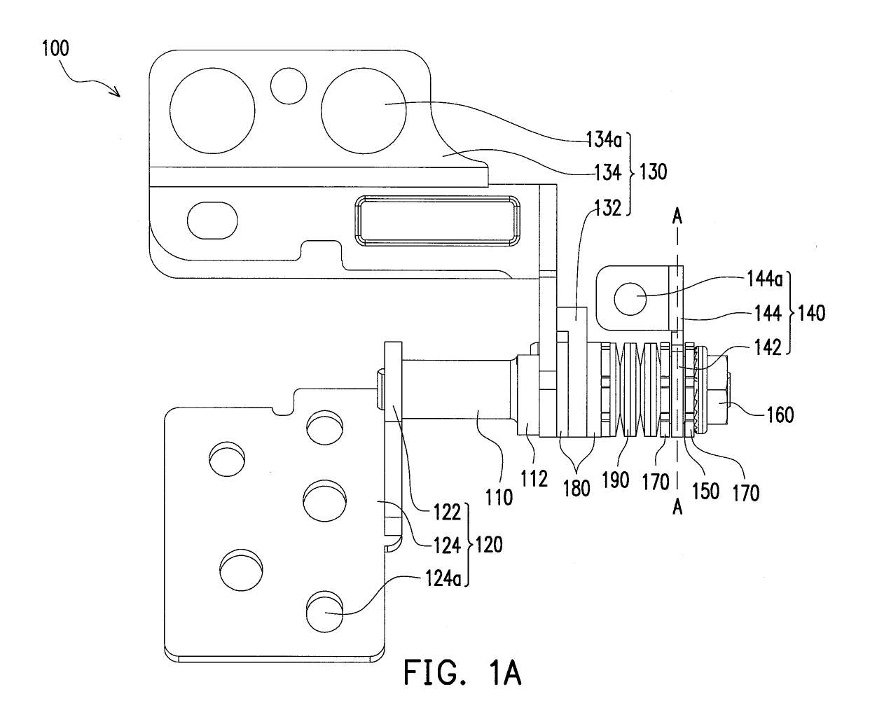

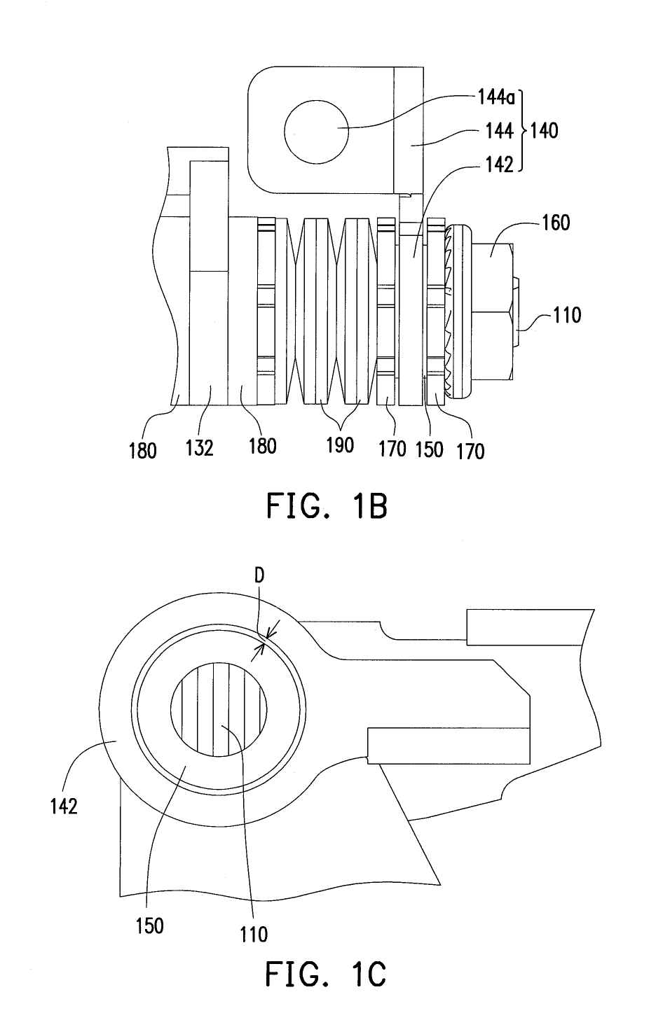

The present invention provides a hinge module applying for a first body pivotally disposed at a second body. FIG. 1A is a schematic view of a hinge module according to one embodiment of the present invention. FIG. 1B is a partial enlarged view of the hinge module in FIG. 1A. FIG. 1C is a schematic cross-sectional view of the hinge module in FIG. 1A along line A-A. Referring to FIG. 1A, FIG. 1B and FIG. 1C, the hinge module 100 of the present embodiment includes an axle 110, a first stand 120, a second stand 130, an auxiliary stand 140, a washer 150 and a pressing element 160.

In the present embodiment, the axle 110 has a baffle 112. The baffle is integrally formed on the axle 110. The first stand 120 includes a first connecting part 122 and a first fixing part 124. The first connecting part 122 is fixed to the axle 110, and the first fixing part 124 is fixed to the first body (not shown). The second stand 130 includes a second connecting part 132 and a second fixing part 134. The second connecting part 132 is pivotally connected to the axle 110, and the second fixing part 134 is fixed to the second body (not shown). The second body is pivotally disposed on the first body by the hinge module 100, so as to rotate relative to the first body.

The auxiliary stand 140 includes a third connecting part 142 and a third fixing part 144. The third connecting part 142 is pivotally connected to the axle 110, and the third fixing part 144 is suitable for being fixed to the first body or the second body. The hinge module 100 of the present embodiment uses the auxiliary stand 140 pivotally connected to the axle 110 and fixed to the first body or the second body to diminish the wobbling situation when the first body rotates relative to the second body.

Because the closer the third fixing part 144 of the auxiliary stand 140 is to the axle 110, the fewer wobbling situation happens when the first body rotates relative to the second body, in the present embodiment, the distance between the third fixing part 144 and the axle 110 is smaller than the distance between the first fixing part 124 or the second fixing part 134 and the axle 110. Therefore, the moment arm from the third fixing part 144 to the axle 110 is smaller than the moment arm from the first fixing part 124 or the second fixing part 134 to the axle 110. If the third connecting part 142 rotates with the axle 110, at the time, the part of the third fixing part 144 fixed to the first body or the second body bears greater tension, such that the part of the first body or the second body fixed to the third fixing part 144 is easily broken.

As shown in FIG. 1C, the washer 150 is disposed between the axle 110 and the third connecting part 142. There is a gap D between the washer 150 and the third connecting part 142. Therefore, in the present embodiment, the third connecting part 142 may easily rotate without the interference of the washer 150. In the present embodiment, the range of the gap D is between 0.1 mm to 0.15 mm. Of course, the range of the gap D should not be construed as limited to the embodiments of the present invention. In other embodiments, there may not be any gap D between the washer 150 and the third connecting part 142. Moreover, the width of the washer 150 along the axial direction of the axle 110 is greater than the width of the third connecting part 142 along the axial direction of the axle 110. In the present embodiment, the material of the washer 150 may be metal. In other embodiments, the material of the washer 150 may also be plastic or other material.

The pressing element 160 is fixed to the axle 110. The second connecting part 132, the third connecting part 142 and the washer 150 is located between the baffle 112 and the pressing element 160. The pressing element 160 provides pressure to the baffle 112 along the axial direction of the axle 110.

In the present embodiment, the pressing element 160 is a cap nut, and the axle 110 has thread corresponding to the pressing element 160. The pressing element 160 is fasten to the axle 110 in a direction toward the baffle 112 so as to provides pressure, but the type of the pressing element 160 and the fixing method thereof is not limited thereto. Due to the axial width of the washer 150 greater than the axial width of the third connecting part 142, the washer 150 of the hinge module 100 of the present embodiment is substituted for the third connecting part 142 to bear the pressure, such that the friction of the auxiliary stand 140 during rotation can be diminished, so as to protect the part of the first body or the second body fixed to the third fixing part 144.

In addition, the hinge module 100 of the present embodiment further includes a pair of first gaskets 170, a pair of second gaskets 180 and an elastic element 190. As shown in FIG. 1A, the pair of first gaskets 170 are disposed on the axle 110. The pair of first gaskets 170 respectively contact two sides of the washer 150. As shown in FIG. 1A, the pair of second gaskets 180 are disposed on the axle 110. The pair of second gaskets 180 respectively contact two sides of the second connecting part 132.

When the second stand 130 rotates relative to the first stand 120, the first gaskets 170 and the second gaskets 180 are configured to provide the washer 150 and the second connecting part 132 with friction. The washer 150 is substituted for the third connecting part 142 to contact the first gaskets 170, such that the auxiliary stand 140 may rotate freely. The friction born by the second connecting part 132 maintains an included angle between the first body and the second body, so as to resist the rotation of the first body or the second body due to gravity impact, etc. In the present embodiment, the material of the first gaskets 170 and the second gaskets 180 may be metal. In other embodiments, the material of the first gaskets 170 and the second gaskets 180 may also be plastic or other material.

The elastic element 190 is disposed on the axle 110 and located between the first gasket 170 and the second gasket 180 adjacent to each other. The elastic element 190 contacts the first gasket 170 and the second gasket 180 adjacent to each other, so as to transmit the pressure provided by the pressing element 160. The acting force of the pressing element 160 is transmitted to the second connecting part 132 through the pair of first gaskets 170, the washer 150 between the pair of first gaskets 170, the elastic element 190 and the second gaskets 180. In the present embodiment, the material of the elastic element 190 is rubber, but the type of the elastic element 190 is not limited thereto.

Because the washer 150 would be slightly deformed after being pressed by the pressing element 160, when free rotation of the auxiliary stand 140 is needed, the axial width of the pressed washer 150 is still needed to be greater than the axial width of the third connecting part 142, such that the pair of first gaskets 170 do not contact the third connecting part 142 of the auxiliary stand 140, and the auxiliary stand 140 may rotate freely, as shown in FIG. 1B. If the rotation difficulty of the auxiliary stand 140 is needed to be increased, because the outer diameter of the washer 150 and the inner diameter of the third connecting part 142 of the present embodiment are smaller than the outer diameter of the pressing element 160, as shown in FIG. 1A, manufacturers may adjust the axial width of the washer 150, the material of the washer 150 or the location where the pressing element 160 fixed to the axle 110, so as to make the axial width of pressed washer 150 close to the axial width of the third connecting part 142. Under this condition, the pair of first gaskets 170 contact the washer 150 and two sides of the third connecting part 142 at the same time, such that the third connecting part 142 bears a holding force so as to provide the auxiliary stand 140 friction when the auxiliary stand 140 is rotating.

The hinge module 100 of the present embodiment may adjust the rotation difficulty by changing the width of the washer 150 along the axial direction of the axle 110, the material of the washer 150 or the location where the pressing element 160 is fixed to the axle 110, such that the auxiliary stand 140 can help maintaining the included angle between the first body and the second body.

In addition, in the present embodiment, each of the first fixing part 124, the second fixing part 134 and the third fixing part 144 has at least one through hole 124a, 134a, 144a for the fasten component such as screw, etc., to pass through, so as to be fasten to the first body or the second body. Of course, in other embodiments, the first fixing part 124, the second fixing part 134 and the third fixing part 144 may also be fixed to the first body and the second body by the method of adhering or engaging.

Due to the current design trend of light weight and compactness of the portable electronic devices, the inner space of the first body and the second body is limited, and, as a result, the first stand and the second stand fixed to the first body and the second body is also needed to be downsized. The hinge module 100 of the present embodiment can be applied to this type of portable electronic device by using auxiliary stand 140 to help being fixed to the first body or the second body, so as to enhance the rotation stability between the hinge module 100 and the first body or the second body.

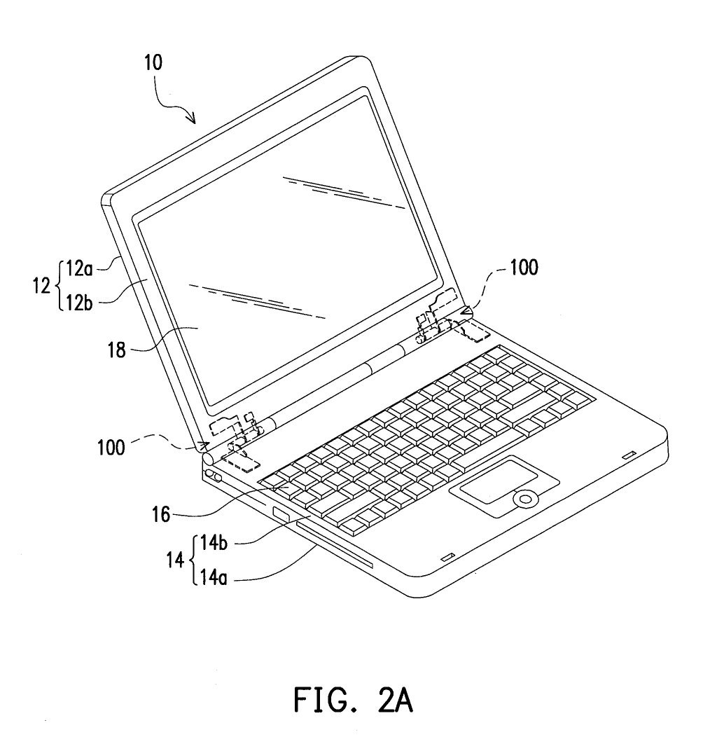

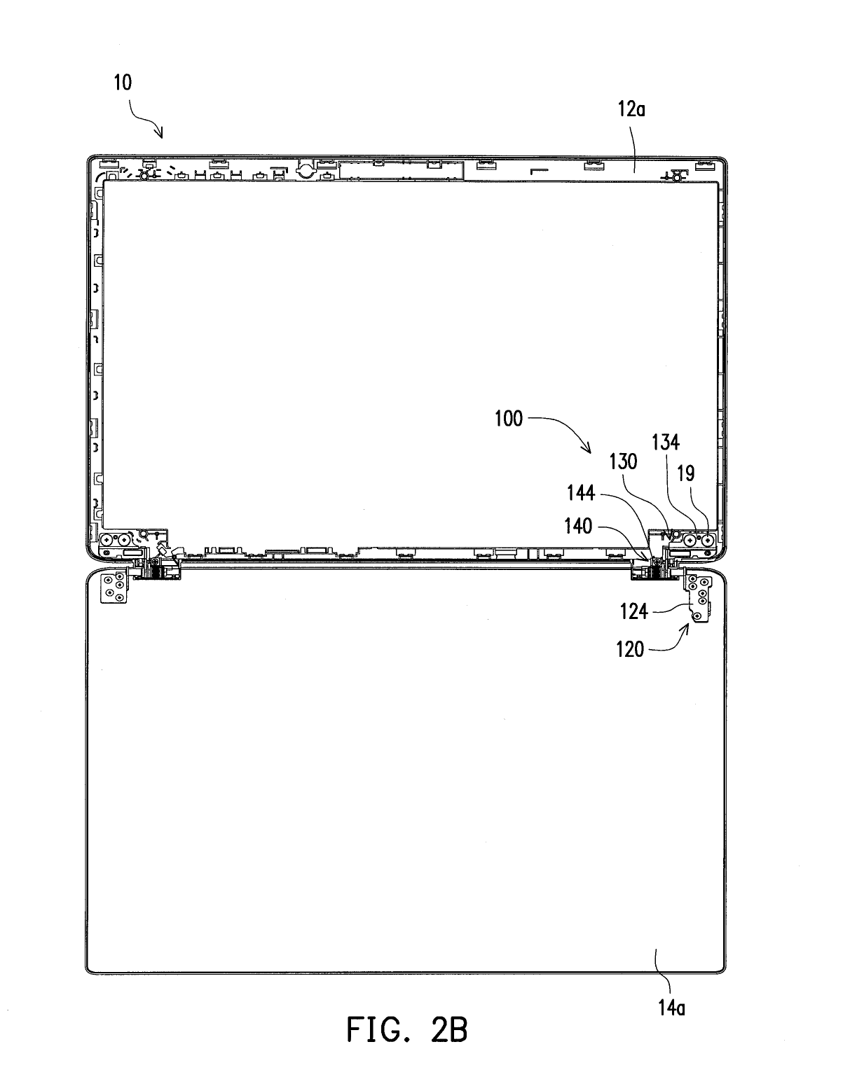

FIG. 2A is a schematic view of a portable electronic device according to an embodiment of the present invention. FIG. 2B is a schematic view of the portable electronic device which the inner casings of the first body and the second body in FIG. 2A is omitted. Referring to FIG. 2A and FIG. 2B, in the present embodiment, the portable electronic device 10 is, for example, a laptop computer, but it is not limited thereto. The portable electronic device 10 of the present embodiment includes a first body 12, a second body 14 and two hinge modules 100. The first body 12 includes an outer housing 12a and an inner casing 12b. The second body 14 includes an outer housing 14a and an inner casing 14b. Moreover, the portable electronic device 10 of the present embodiment further includes a keyboard module 16 and a display module 18. The keyboard module 16 is disposed at the inner casing 12b of the first body 12. The display module 18 is disposed at the inner casing 14b of the second body 14.

In order to illustrate the connecting relationship between the hinge module 100, the first body 12 and the second body 14 more clearly, the inner casing 12b, 14b of the first body 12 and the second body 14 are omitted in FIG. 2B, and only the outer housing 12a, 14a of the first body 12 and the second body 14 and the two hinge module 100 are illustrated. In the present embodiment, the portable electronic device 10 adopts the hinge module 100 in FIG. 1A. The first fixing parts 124 of the first stands 120 of the two hinge modules 100 are fixed to the outer casing 12a of the first body. The second fixing parts of the second stands 130 and the third fixing parts 144 of the auxiliary stands 140 of the two hinge modules 100 are fixed to the outer housing 14a of the second body 14. In other embodiments, the third fixing parts 144 may also be fixed to the outer housing 12a of the first body 12.

It is noted that, the location of the auxiliary stands 140 are not limited in FIG. 2B. The auxiliary stands 140 are configured to enhance the stability of the pivot connection between the first body 12 and the second body 14. Manufacturers may adjust the location and the shape of the third fixing parts 144 of the auxiliary stands 140 according to the inner space arrangement of first body 12 or the second body 14 needed to be fixed to the auxiliary stands 140.

In addition, the outer housing 12a of the first body 12 and the outer housing 14a of the second body 14 respectively have a plurality of threaded holes. The locations of the threaded holes correspond to the locations of the through holes of the first fixing parts 124, the second fixing parts 134 and the third fixing parts 144 for the fasten components 19 to penetrate through and fix the first stands 120, the second stands 130 and the auxiliary stands 140 to the first body 12 and the second body 14. Of course, in other embodiments, the first fixing parts 124, the second fixing parts 134 and the third fixing parts 144 may also be fixed to the first body 12 and the second body 14 by the method of adhering or engaging. It is not limited thereto.

In the present embodiment, the portable electronic device has more stable pivot connecting relationship between the first body and the second body with the help of the auxiliary stand, and by means of the axial widths of the washers greater than the axial widths of the third connecting parts, the pressure provided by the pressing elements is transmitted to the second connecting parts by the washers. When the first body rotates relative to the second body, the auxiliary stands diminish the negative impact from the torsion of the hinge module, so as to elongate the lifetime of the connection between the auxiliary stands and the first body or the second body.

In sum, the hinge module of the present invention uses the auxiliary stand thereof to enhance the stability of the pivot connection and uses the washer to prevent the auxiliary from breaking the connected body when rotating, so as to elongate the lifetime of the products. Moreover, in the present invention, the rework between the hinge module and the first body or the second body is simple, so as to significantly improve the convenience in manufacture and maintenance. Manufacturers may adjust the rotation difficulty of the auxiliary stand by changing the axial width of the washer or the location where the pressing element is fixed to the axle according to actual demands. The portable electronic device of the present invention enables the second body to rotate relative to the first body stably by adopting the above mentioned hinge module.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A hinge module, applying for a first body pivotally disposed at a second body, the hinge module comprising:
an axle, having a baffle;
a first stand, comprising a first connecting part and a first fixing part, the first connecting part fixed to the axle, and the first fixing part fixed to the first body;
a second stand, comprising a second connecting part and a second fixing part, the second connecting part pivotally connected to the axle, and the second fixing part fixed to the second body;
an auxiliary stand, comprising a third connecting part and a third fixing part, the third connecting part pivotally connected to the axle, and the third fixing part suitable for being fixed to the first body or the second body;
a washer, disposed on the axle and located between the axle and the third connecting part, a width of the washer along an axial direction of the axle greater than a width of the third connecting part along the axial direction of the axle; and
a pressing element, fixed to the axle, wherein the second connecting part, the third connecting part and the washer are located between the baffle and the pressing element, the pressing element providing pressure to the baffle along the axial direction of the axle.

2. The hinge module as claimed in claim 1, further comprising:
a pair of first gaskets, disposed on the axle, and the washer located between the pair of first gaskets.

3. The hinge module as claimed in claim 2, further comprising:
a pair of second gaskets, disposed on the axle, and the second connecting part located between the pair of second gaskets.

4. The hinge module as claimed in claim 3, further comprising:
an elastic element, disposed on the axle and located between the first gasket and the second gasket adjacent to each other.

5. The hinge module as claimed in claim 1, wherein a distance between the third fixing part and the axle is smaller than a distance between the first fixing part or the second fixing part and the axle.

6. The hinge module as claimed in claim 1, wherein an outer diameter of the washer and an inner diameter of the third connecting part are smaller than an outer diameter of the pressing element.

7. A portable electronic device, comprising:
a first body;
a second body; and
at least one hinge module, each of the hinge module comprising:
an axle, having a baffle;
a first stand, comprising a first connecting part and a first fixing part, the first connecting part fixed to the axle, and the first fixing part fixed to the first body;
a second stand, comprising a second connecting part and a second fixing part, the second connecting part pivotally connected to the axle, and the second fixing part fixed to the second body;
an auxiliary stand, comprising a third connecting part and a third fixing part, the third connecting part pivotally connected to the axle, and the third fixing part suitable for being fixed to the first body or the second body;
a washer, disposed on the axle and located between the axle and the third connecting part, the width of the washer along an axial direction of the axle greater than the width of the third connecting part along the axial direction of the axle; and
a pressing element, fixed to the axle, the second connecting part, the third connecting part and the washer located between the baffle and the pressing element, the pressing element providing pressure to the baffle along the axial direction of the axle.

8. The portable electronic device as claimed in claim 7, further comprising:
a keyboard module and a display module, each of the first body and the second body having an outer housing and an inner casing, the keyboard module located at the inner casing of the first body, and the display module located at the inner casing of the second body.

9. The portable electronic device as claimed in claim 8, wherein the first fixing part is fixed to the outer housing of the first body, the second fixing part and the third fixing part are fixed to the outer housing of the second body.

10. The portable electronic device as claimed in claim 7, wherein the hinge module further comprising:
a pair of first gaskets, disposed on the axle, and the washer located between the pair of first gaskets.

11. The portable electronic device as claimed in claim 10, wherein the hinge module further comprising:
a pair of second gaskets, disposed on the axle, and the second connecting part located between the pair of second gaskets.

12. The portable electronic device as claimed in claim 11, wherein the hinge module further comprising:
an elastic element, disposed on the axle and located between the first gasket and the second gasket adjacent to each other.

13. The portable electronic device as claimed in claim 7, wherein a distance between the third fixing part and the axle is smaller than a distance between the first fixing part or the second fixing part and the axle.

14. The portable electronic device as claimed in claim 7, wherein an outer diameter of the washer and the inner diameter of the third connecting part are smaller than an outer diameter of the pressing element.
